(19) United States
(12) Patent Application Publication
(10) Pub. No.: US 2019/0271736 A1
(43) Pub. Date: Sep. 5, 2019

(54) SYSTEM FOR CHARACTERIZING A POWER DIODE

(71) Applicant: COMMISSARIAT A L'ENERGIE ATOMIQUE ET AUX ENERGIES ALTERNATIVES, Paris (FR)

(72) Inventors: William VANDENDAELE, Grenoble (FR); Thomas LORIN, Grenoble (FR)

(73) Assignee: COMMISSARIAT A L'ENERGIE ATOMIQUE ET AUX ENERGIES ALTERNATIVES, Paris (FR)

(21) Appl. No.: 16/347,731

(22) PCT Filed: Nov. 6, 2017
(86) PCT No.: PCT/FR2017/053026

§ 371 Date: May 6, 2019

(30) Foreign Application Priority Data
Nov. 9, 2016 (FR) 1660871

(51) Int. Cl. G01R 31/26

(52) U.S. Cl. CPC G01R 31/2633

(57) ABSTRACT

The invention relates to a characterization device for a power diode including: first and second power supply nodes; a power supply (including a first voltage source connected to the first node; a second voltage source; a first resistor connected in series between the second voltage source and said second node; and a controlled switch for selectively connecting the second node to a potential lower than a first potential); and a voltage clipping circuit (including a third voltage source; a second resistor and a first diode connected in series between the third voltage source and said second node; and a measurement terminal, connected to an intermediate node between the second resistor and the first diode).

The invention relates to the characterization of power electronic components and, in particular, measurement devices designed to analyze the behavior of a power diode after switching between its non-conducting state and its conducting state.

A power diode must be characterized in order to be able to anticipate its behavior during various phases of operation. This characterization allows the behavior of circuits such as rectifiers or converters, into which one or more power diodes may be integrated, to be anticipated. The characterization must notably cover the switching phases in order to know the switching energy upon closing, the switching energy upon opening, the corresponding dynamic forward-bias resistances, the reverse-bias recovery time, or the reverse-bias recovery charges.

The heterojunction diodes used in power circuits are the subject of significant development efforts. Indeed, such diodes exhibit high breakdown voltages, reduced forward-bias resistances and reduced switching times. Such diodes are for example formed on GaN substrates. As opposed to diodes formed on silicon substrates, heterojunction diodes suffer from current drops in the conducting state. These current drop phenomena remain poorly understood and difficult to predict. For such heterojunction diodes, the characterization in the conducting state both over short time scales and over long time scales may thus prove crucial in both a research and in an industrial framework.

With a view to characterizing a power diode, the company Keysight Technologies is marketing a connection module for a diode under the reference N1267A and a power characterization module under the reference B1505, whose combination can form a characterization device that will be designated as reference characterization device. The power characterization module comprises a high-voltage source, a current source and a driver/controller circuit. The power diode to be tested is connected to the connection module. The connection module comprises a switching transistor driven by the driver/controller circuit of the power characterization module. The power characterization module carries out the characterization of the power diode based on the current flowing through it, by measuring the difference between the current supplied by the high-voltage source and the current supplied by the current source.

Such a reference characterization device exhibits a relatively high level of error and level of sensitivity to noise. Furthermore, such a circuit exhibits a switching time for the power diode of more than 100 μs, which does not allow this power diode to be characterized at short time scales following the switching.

Thus, no known solution allows a power diode to be characterized for a period of time following the switching going from around 50 ns to several tens of seconds. Nor does any known solution allow a power diode to be characterized with a sufficiently high precision. There is accordingly a need for a device for characterizing a power diode exhibiting a high precision and allowing the power diode to be characterized both over short time scales and over long time scales. There furthermore exists a need for such a characterization device at a reasonable cost.

The document ‘Characteristics of a High-Current, High-Voltage Shockley Diode’ in IEEE Transactions on Electron Devices, Vol Ed-17, N° 9, pages 694-705, by Walter Schroen, describes various circuits for testing diodes, for testing respective behaviors of a diode while switching to a conducting state or to a non-conducting state. The circuit used for characterizing the switching of a diode to the conducting state has a poor performance, notably for measuring fast switching operations.

The document U.S. Pat. No. 2,950,439 describes the use of several voltage sources for implementing a diode test.

The document U.S. Pat. No. 3,648,168 describes a circuit for testing a diode, for characterizing both its switching to the conducting state and its switching to the non-conducting state.

The document U.S. Pat. No. 3,659,199 describes a circuit for testing a diode, including a function for heating up the diode by a calibrated current.

The invention aims to solve one or more of these drawbacks. The invention thus relates to a system such as defined in the appended claim 1.

The invention also relates to variants in the dependent claims. Those skilled in the art will understand that each of the features of the variants in the dependent claims may be independently combined with the features of claim 1, without however constituting an intermediate generalization.

Other features and advantages of the invention will become clearly apparent from the description of it presented hereinafter, by way of non-limiting example, with reference to the appended drawings, in which:

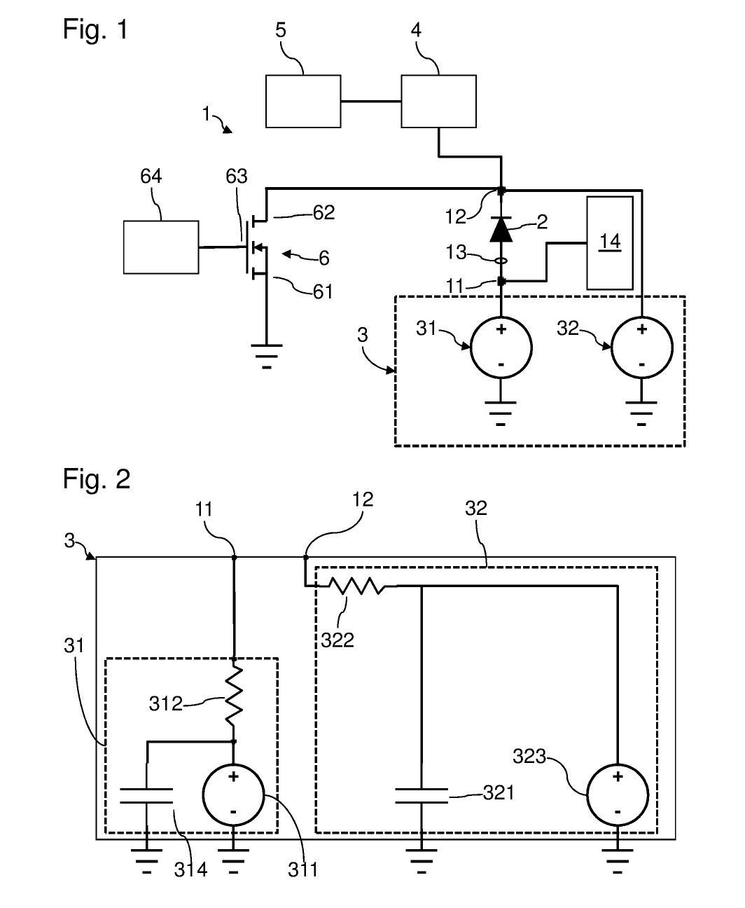

FIG. 1 shows schematically an example of a device for characterization of power diodes according to one exemplary embodiment of the invention;

FIG. 2 shows schematically a first variant of power supply of the characterization device;

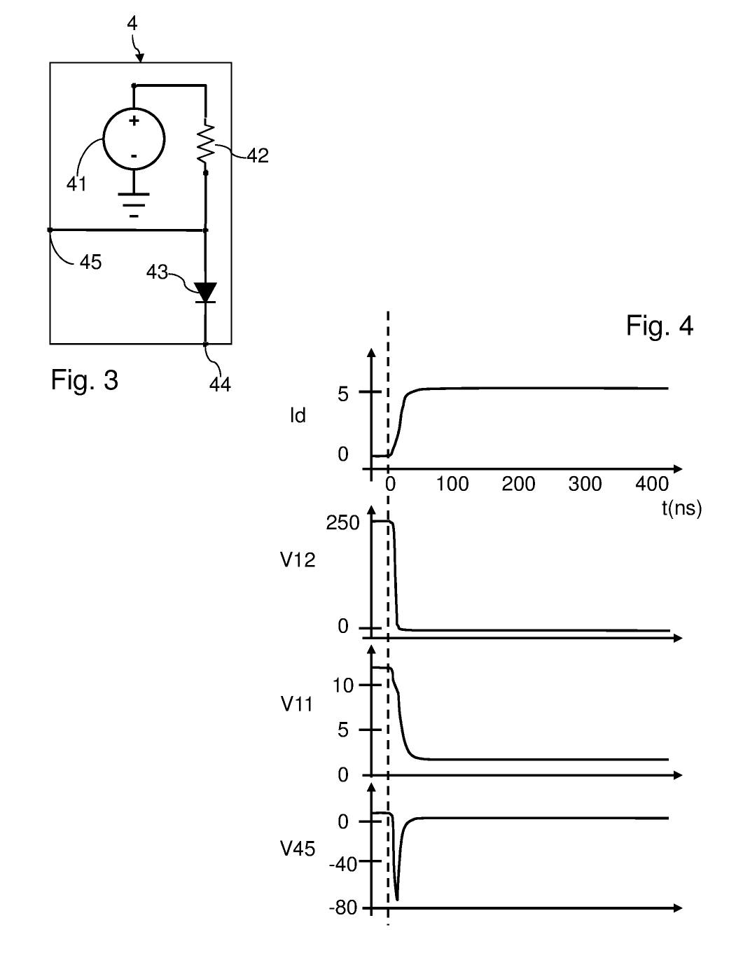

FIG. 3 shows schematically a first variant of a clipping circuit according to the invention;

FIG. 4 is a diagram illustrating the variation of various measured parameters over time when the diode is closed;

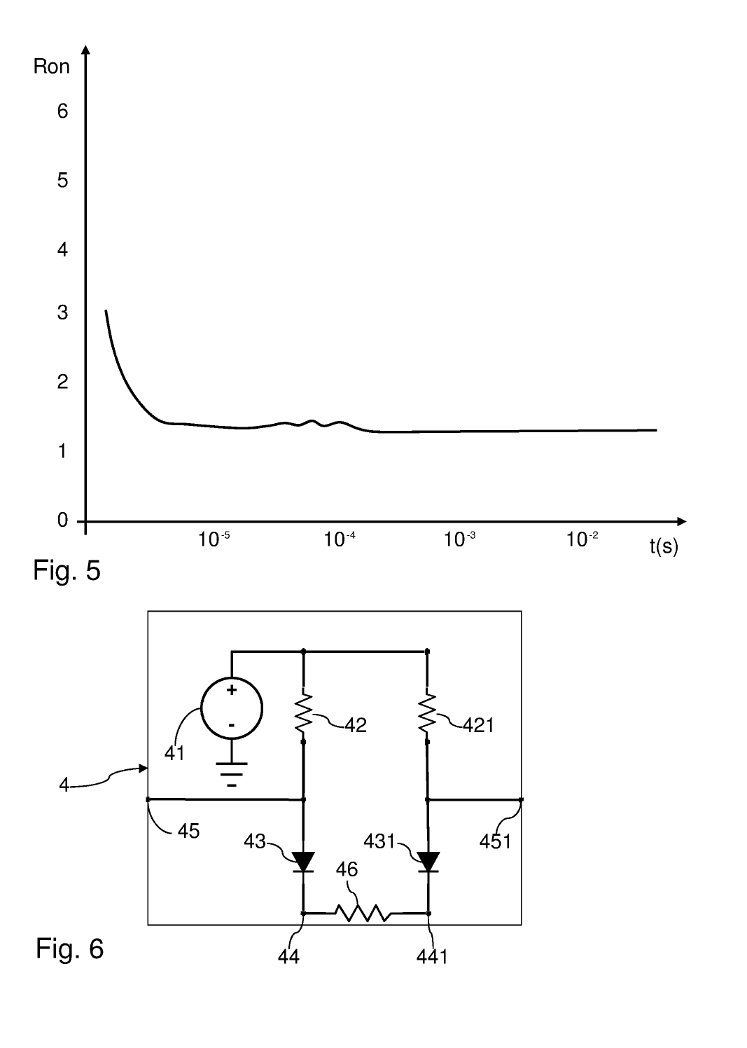

FIG. 5 illustrates the variation over time in the conducting state of the conduction resistance of a diode following its closing;

FIG. 6 shows schematically a second variant of clipping circuit according to the invention;

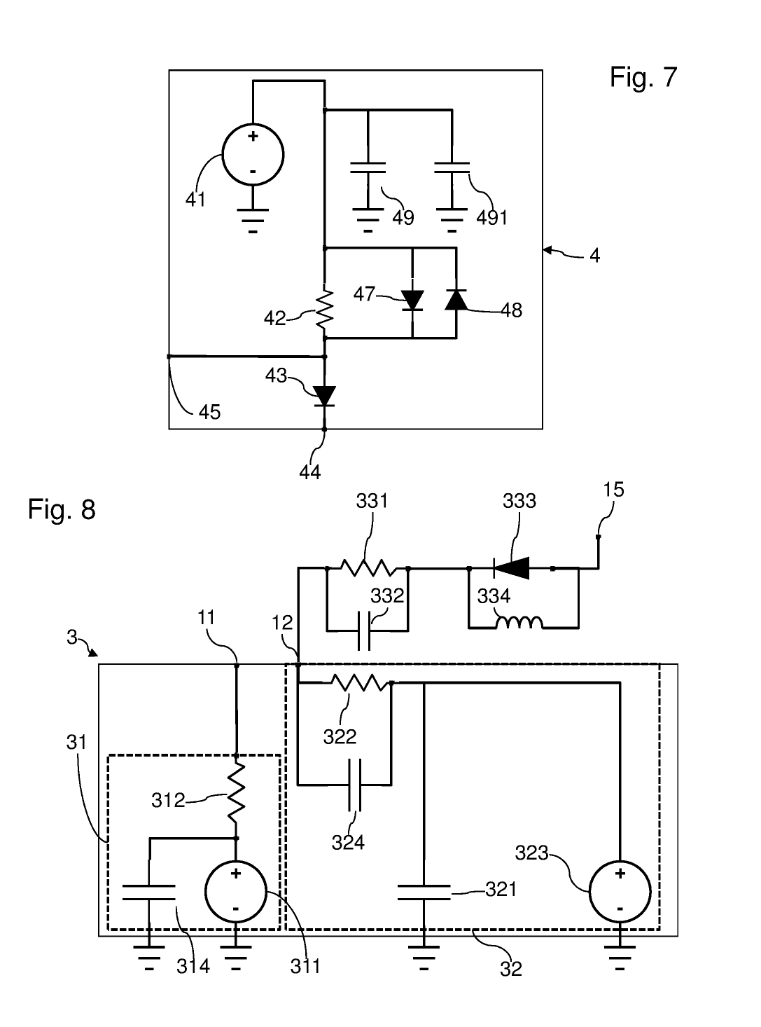

FIG. 7 shows schematically a third variant of clipping circuit according to the invention;

FIG. 8 shows schematically a second variant of power supply of the characterization device;

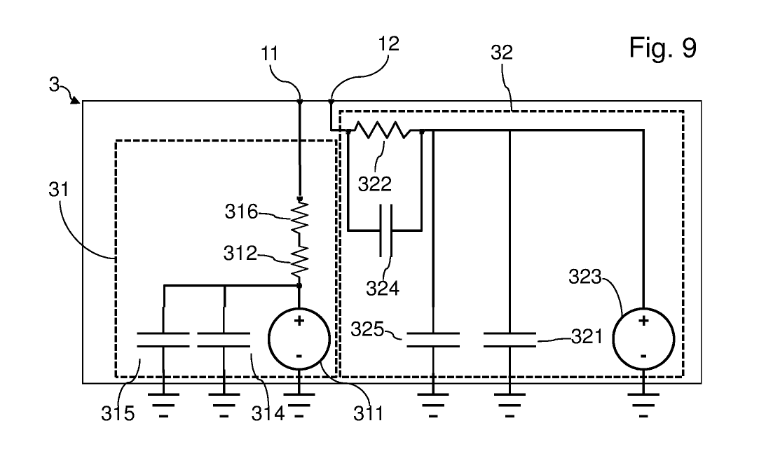

FIG. 9 shows schematically a third variant of power supply of the characterization device.

The invention provides a device for characterizing a power diode. This device notably comprises a power supply comprising a voltage source designed to supply a high voltage to the cathode of the diode to be characterized for the non-conducting state of this diode, and another voltage source designed to supply a high current when the diode is closed. A capacitor is connected in parallel with the source designed to supply a high current.

The characterization device furthermore comprises a voltage clipping circuit using an additional DC voltage source, with a measurement terminal connected to an intermediate node between a resistor and a diode, the resistor and the diode being connected in series on an output of this additional DC voltage source.

FIG. 1 illustrates schematically a power diode 2 forming a component to be tested, connected to a characterization device 1. The power diode 2 is for example a heterojunction diode.

The characterization device 1 comprises power supply nodes 11 and 12. The diode 2 comprises an anode connected to the power supply node 11, and a cathode connected to the power supply node 12. The characterization device 1 furthermore comprises an electrical power supply 3. The power supply 3 comprises a power supply circuit 31 and a power supply circuit 32. The power supply circuit 31 applies an output voltage to the power supply node 11. The power supply circuit 32 applies an output voltage to the power supply node 12. The characterization device 1 also comprises a voltage clipping circuit 4 an input of which is connected to the power supply node 12 and an output of which here is connected to an acquisition device 5.

The characterization device 1 furthermore comprises a controlled switch 6. The controlled switch 6 comprises a first conduction electrode 61, here connected to a ground potential, a second conduction electrode 62 connected to the power supply node 12 and a control electrode 63. A control circuit 64 is configured for selectively applying an opening signal and a closing signal to the control electrode 63 of the controlled switch 6. The control circuit 64 may for example sequentially control opening and closing operations of the controlled switch 6. The controlled switch 6 is dimensioned so as to have a breakdown voltage higher than the voltage applied to the power supply node 12. The controlled switch 6 consists for example of a field-effect transistor, for example a field-effect transistor with high electron mobility (exhibiting a high breakdown voltage and a very reduced switching time) or an SiC MOSFET transistor (also exhibiting a very reduced switching time). The electrodes 61, 62 and 63 are then respectively the source, the drain and the control gate of this transistor. When such a transistor is closed so as to form a current demand through the diode 2 to be characterized, it is used in its first quadrant, its switching speed then being optimal.

The characterization device 1 here furthermore comprises a current probe 13 measuring the current between the power supply nodes 11 and 12 (corresponding to the current flowing through the diode 2) and a voltmeter (or a voltage probe) 14 measuring the voltage on the power supply node 11.

FIG. 2 illustrates a first variant of a power supply 3 for the implementation of the invention. The power supply 3 comprises the power supply circuit 31 designed to apply a high current through the power diode 2 in its closed state, via the power supply node 11, when a current is demanded by the controlled switch 6. The power supply circuit 31 is also designed to render the diode 2 conducting under conditions where the potential difference between the power supply node 11 and the power supply node 12 is higher than the threshold voltage of the diode 2. The power supply 3 also comprises the power supply circuit 32 designed to apply a high voltage to the power supply node 12, the level of this high voltage serving to maintain the diode 2 in its open state, in the absence of a current demand by the controlled switch 6.

The power supply circuit 31 comprises a DC voltage source 311 generating a first power supply potential with respect to a ground potential. The first power supply potential is at least higher than the potential applied to the electrode 61 of the controlled switch 6. The DC voltage source 311 is configured so as to be able to supply a high current, typically equal to at least 1 A, preferably equal to at least 5 A, and advantageously equal to at least 10 A. The DC voltage source 311 is configured for generating a maximum supply potential lower than the maximum supply potential of the DC voltage source 323 (detailed hereinbelow), typically 20 V at the most. The diode 2 is connected between the power supply nodes 11 and 12 in such a manner that a forward current flows through it going from the voltage source 311 toward the power supply node 12 when it is made to conduct.

A resistor 312 here is advantageously connected in series with the diode 2 between the voltage source 311 and the power supply node 12. The power supply circuit 31 comprises a capacitor 314 connected in parallel with the DC voltage source 311. In order to help the source 311 to supply a high current over short time scales, it is thus preferable to add a power supply capacitance between the voltage source 311 and the resistor 312, here in the form of the capacitor 314. The values of these capacitances will be advantageously chosen so as to cover the short time scales, typically shorter than 10 ms. Beyond this, the voltage source 311 will supply the desired current over longer time scales. The various decoupling capacitors detailed in the following part are aimed at stabilizing the power supplies over a wide range of frequencies and thus limiting as far as possible the oscillations of the circuits in order to gain in speed. By virtue of the various decoupling capacitors detailed in the various variants, the stability of the voltages from the corresponding circuit are perfectly controlled.

The power supply circuit 32 comprises a DC voltage source 323 generating a second power supply potential with respect to the ground potential. The second power supply potential is higher than the first power supply potential. The second power supply potential has an amplitude for which the diode 2 must be characterized in the non-conducting state. The second power supply potential is for example equal to at least 100 V, preferably equal to at least 500 V, and advantageously equal to at least 1000 V, depending on the diode 1 that needs to be characterized.

The circuit 32 comprises a resistor 322 connected in series between the DC voltage source 323 and the power supply node 12. The resistor 322 allows the voltage source 323 to be protected from the current supplied by the voltage source 311. The resistor 322 also allows a voltage drop to be created between the voltage source 323 and the power supply node 12 when the diode 2 is conducting, and allows the voltage source 323 to be stabilized. The circuit 32 here advantageously comprises a decoupling capacitor 321 connected in parallel with the DC voltage source 323.

In contrast to a transistor, a diode does not have a control gate and must be directly switched by the difference in potential between its anode and its cathode. The potentials on the anode and the cathode must be driven at high speed in order to be able to study short-time-scale phenomena. The anode and the cathode must be able to alternately handle a high voltage and a high current.

The inventors have identified several problems with the reference characterization device solved by a characterization device according to the invention. Thus, in the reference characterization device, the characterization of the power diode is based on a deduction of the current flowing through it. This deduction is carried out by the differential measurement between the current supplied by the voltage source and the current supplied by the current source. This differential measurement represents a considerable source of error. Furthermore, the transistor of the connection module of the reference characterization device is used in its third quadrant, which considerably increases its switching time (owing to phenomena of reverse-bias recovery of the diode intrinsic to this field-effect transistor on a silicon substrate). Furthermore, the current source and the voltage source for the characterization module of the reference characterization device are of the SMU (for Source Measure Unit) type and thus operate both as a measurement source and as a measurement device. Such sources of the SMU type include regulation loops whose response time is high and dependent on the forward-bias resistance of the power diode, which also increases the switching time of the transistor of the connection module. Furthermore, such sources of the SMU type use the same measurement gauge designed for high currents, which greatly affects the precision of the measurement for low currents.

FIG. 3 shows schematically a first variant of clipping circuit 4 according to the invention. This clipping circuit 4 will be detailed before studying the operation of the characterization device 1, on the basis of exemplary measurements carried out by means of this clipping circuit 4.

The clipping circuit 4 comprises a DC voltage source 41 generating a third power supply potential with respect to a ground potential. The third potential typically has a potential less than or equal to 10 V. The clipping circuit 4 furthermore comprises a resistor 42 and a diode 43 connected in series between the voltage source 41 and an input terminal 44. The input terminal 44 is, in practice, connected to the power supply node 12. The diode 43 is connected in such a manner that a forward current flows through it going from the voltage source 41 toward the input terminal 44. A measurement terminal 45 is connected to an intermediate node between the resistor 42 and the diode 43. The measurement terminal 45 is thus connected to the anode of the diode 43.

The clipping circuit 4 allows a potential problem of saturation of an oscilloscope or of an acquisition device 5 connected to the measurement terminal 45 to be overcome, which allows the measurement resolution to be substantially increased while at the same time remaining compatible with the level of voltage applied to the power supply node 12 when the controlled switch 6 is open. The measurement of the voltage of the power supply node 12 is made behind the diode 43. When the voltage on the power supply node 12 is higher than the third power supply potential, the diode 43 is reverse biased and the current flowing through it is extremely low. The voltage on the measurement terminal 45 cannot exceed the third power supply potential.

When the voltage on the power supply node 12 (added to the threshold voltage of the diode 43) becomes lower than the third power supply potential, the diode 43 is forward biased and behaves substantially as a closed switch. The voltage applied to the measurement terminal 45 corresponds to the threshold voltage minus the voltage drop caused by the diode 43. The range of voltage on the power supply node 12 when the controlled switch 6 is closed may be adjustable with the bias voltage of the diode 43.

Starting from the voltage applied to the output terminal 45, the acquisition device 5 may perform a conversion of this voltage into the value of voltage present on the power supply node 12. This conversion may be carried out by means of a conversion circuit of the acquisition device 5. The conversion device may be calibrated on the basis of prior measurements.

For example, the calibration may be performed in the following manner. The controlled switch 6 is maintained in the closed state and the voltage on the measurement terminal 45 is measured in this configuration, in order to define an offset value. Subsequently, the controlled switch 6 is held in the open state, by applying another power supply potential of a predetermined level. An affine conversion law may then be determined as a function of these voltage measurements. The conversion circuit may then be programmed to use this affine conversion law, supplying the voltage on the power supply node 12 as a function of the voltage on the output terminal 45.

FIG. 4 comprises the diagram illustrating the variation of various parameters as a function of time following the closing of the diode 2, these parameters being measured by means of the acquisition device 5.

The diagram illustrates, from top to bottom, the current Id flowing through the diode 2, the potential on the power supply node 12, the potential on the power supply node 11, and the potential on the output terminal 45.

Before the time t=0, the controlled switch 6 is held open. Since the current flowing through the resistor 322 is substantially zero, the power supply circuit 32 maintains a potential on the node 12 higher than the potential maintained by the power supply circuit 31 on the node 11. The diode 2 is thus held in a non-conducting state and a reverse current of substantially zero flows through it. The current supplied by the power supply source 311 is zero.

At the time t=0, the control circuit 64 commands the closing of the controlled switch 6. The electrode 62 is brought substantially to ground potential. The controlled switch 6 then implements a current demand. The power supply circuit 32 supplies a current through the resistor 322, thus causing the potential on the power supply node 12 to fall down to a level lower than the potential on the power supply node 11. The diode 2 thus switches into the conducting state. The voltage source 311 then supplies a current through the diode 2, and the potentials on the power supply nodes 11 and 12 fall, the potential on the power supply node 11 remains higher than the potential on the power supply node 12.

Advantageously, the power supply circuits 31 and 32 are lacking measurement circuits and corresponding regulation loops, and thus exhibit a particularly high dynamic performance. FIG. 5 illustrates the variation over time in the conducting state of the conduction resistance of the diode 2, measured with a characterization device 1 according to the invention. It is thus observed that the very high dynamic performance of the power supply circuits 31 and 32 allows a characterization over very short times to be obtained. Furthermore, it is observed that the very high precision of the characterization device allows phenomena such as resistance drops in the conducting state to be detected (c.f. ripples in the diagram between around t=10⁻⁵ and t=10⁻⁴), for example attributed to de-trapping effects in the substrate. Furthermore, a voltage source 311 is not based on a capacitive discharge and can therefore allow the diode 2 closed over long time periods to continue to be characterized.

The use of a current probe 13 in series with the diode 2 to be characterized allows a direct measurement of the current flowing through the diode 2 to be obtained, improving the measurement precision. A current probe 13 such as that marketed under the reference TCP0030 may for example be used. A coaxial shunt or a shunt resistor may also be used for measuring the current flowing through the diode 2. The current measurement device advantageously has a bandwidth that is sufficiently wide to cover the short times (<1 μs) to the long times (several seconds or minutes).

For the power supply nodes 11 and 12, the characterization device 1 may comprise a connection system of the socket type and/or a connection system of the cables with probe points type, in order to be able for example to directly apply potentials to a diode of a silicon wafer. A connection of the Kelvin type may also be envisioned, in order to avoid voltage measurements at the points of passage of current, thus avoiding a problem of quality of contact with probe-point cables.

Advantageously, the characterization device 1 comprises another power supply node not shown. This other power supply node is configured for a back face biasing of the substrate of a diode 2 of the lateral type. This other power supply node is for example configured for applying a desired potential, such as that of the anode or that of the cathode of the diode 2. For this purpose, connection terminals may be connected to the power supply nodes 11 and 12, in order to be able to connect this other power supply node to their potentials. Such a biasing scheme minimizes the effects of trapping of charges generated for heterojunction diodes after a reverse biasing at high voltage.

FIG. 6 illustrates a second variant of clipping circuit 4 for the implementation of the invention. The clipping circuit 4 again uses the DC voltage source 41, the resistor 42, the diode 43, the input terminal 44 and the measurement terminal 45 of the variant in FIG. 3. The clipping circuit 4 here furthermore comprises a resistor 421 and a diode 431 connected in series between an output node of the voltage source 41 and another input terminal 441. The input terminals 44 and 441 are connected via a resistor 46. An intermediate node between the resistor 421 and the diode 431 is connected to another measurement terminal 451. The anode of the diode 431 is connected to the measurement terminal 451 and the cathode of the diode 431 is connected to the input terminal 441.

FIG. 7 illustrates a third variant of clipping circuit 4 for the implementation of the invention. The clipping circuit 4 again uses the DC voltage source 41, the resistor 42, the diode 43, the input terminal 44 and the measurement terminal 45 of the variant in FIG. 3.

Diodes 47 and 48 are each connected in parallel with the resistor 42. The anode of the diode 48 is connected to the cathode of the diode 47 and the cathode 48 is connected to the anode of the diode 47. The diodes 47 and 48 allow a voltage spike during the switching of the controlled switch 6 to be limited, which spike may be induced by a relatively high capacitance of the diode 43. The diodes 47 and 48 are for example chosen so as to have a very short forward-bias recovery time.

The clipping circuit 4 furthermore comprises decoupling capacitors 49 and 491 each connected in parallel with the DC voltage source 41.

The capacitor 49 may be a multilayer ceramic capacitor marketed under the reference VJ1812Y104KXET by the company Vishay, with a capacitance of 100 nF, for a DC voltage of 500 V. The capacitor 491 may be a multilayer ceramic capacitor marketed by the company Murata under the reference GRM188R72A104KA35D, with a capacitance of 100 μF, for a DC voltage of 100 V.

The diode 43 will advantageously exhibit a forward-bias recovery time equal to 1 μs at the most and a breakdown voltage equal to at least 100 V. The diode 43 may for example be a diode marketed by the company Vishay under the reference VS-8ETH06SPbF, exhibiting a breakdown voltage of 600 V, a DC forward current of 8 A, and a forward-bias recovery time of 25 ns. The diode 43 may also be a diode marketed by the company Vishay under the reference HFA06TB120SPbF, exhibiting a breakdown voltage of 1200 V, a DC forward current of 8 A, and a forward-bias recovery time of 80 ns. A diode 43 marketed under the reference STTH812 by the company STMicroelectronics may also be used, and notably exhibits a forward-bias recovery time 250 ns, a breakdown voltage of 1200 V and a DC forward current of 8 A. A resistor 42 of the CMS type, marketed by the company Panasonic under the reference ERA6ARW102V may be used, for example with a resistance value of 1 kn. The diodes 47 and 48 may for example be diodes marketed by the company Vishay under the reference GSD2004W.

As an alternative to the various aforementioned diodes, based on a silicon structure, it is possible to use one or more diodes (for the diode 43, the diode 47 or the diode 48) of the SiC type which exhibit a forward-bias recovery time of virtually zero. The diode marketed by the company STMicroelectronics under the reference STTH512B-TR, or the diode marketed by the company Semisouth under the reference SDP30S120 for example prove to be suitable.

The connection system of the voltage source 311 may for example be of the BNC type for a board edge mounting. The connection system for the voltage source 41 and for the measurement terminal 45 is for example of the BNC type. The connection system for the voltage source 323 and for the power supply node 12 may for example be of the SHV type.

The components of the characterization device 1 are advantageously fixed onto a substrate with a thickness of 1.2 mm of the FR-4 type, equipped with a ground plane. The conducting tracks could for example have a width of 1.7 mm, with a spacing of 600 μm. The thickness of the tracks could for example be 35 μm. The substrate could for example be a dielectric with a thickness of 1.2 mm and with a relative permittivity of 4.6.

FIG. 8 illustrates a second variant of a power supply 3 for the implementation of the invention. The circuit 31 here is identical to that detailed with reference to FIG. 2. This circuit 32 differs from the circuit 32 in FIG. 2 only by the presence of a capacitor 324 connected in parallel with the resistor 322.

Independently of the structure of the circuits 31 and 32, this variant comprises a configurable load circuit using RLC components connected between the power supply node 12 and a node 15 intended to be connected to the clipping circuit 4. The presence of such an RLC circuit allows the behavior of the diode 2 to be characterized in the presence of electrical loads of various types.

In the present variant, the RLC circuit comprises two modules connected in series. The first module comprises a resistor 331 and a capacitor 332 connected in parallel. The second module comprises an inductor 334 and a diode 333. The diode 333 is connected to the power supply node 33 via its anode, and its cathode is connected to the first module.

FIG. 9 illustrates a third variant of a power supply 3 for the implementation of the invention, which allows the power supplies to be stabilized over a wider frequency spectrum. This circuit 31 differs from the circuit 31 in FIG. 2:
by the presence of a decoupling capacitor 315 in parallel with the voltage source 311 and with the capacitor 314;
by the presence of a resistor 316 (with a view to easier dissipation of the heat) connected in series with the resistor 312 between the voltage source 311 and the power supply node 11.

The circuit 32 of this third variant differs from the circuit 32 in FIG. 2 by the presence of a decoupling capacitor 325 in parallel with the voltage source 323 and with the capacitor 321 and by the presence of a capacitor 324 connected in parallel with the resistor 322.

The capacitor 314 may be a multilayer ceramic capacitor marketed under the reference VJ1812Y104KXET by the company Vishay, with a capacitance of 100 nF, for a DC voltage of 500 V. The capacitor 315 may be a multilayer ceramic capacitor marketed by the company Murata under the reference GRM188R72A104KA35D, with a capacitance of 100 μF, for a DC voltage of 100 V. The capacitors 321 and 325 could be encased capacitors in the 1812 format, such as capacitors marketed under the references Syfer 1812J2K00102KXT (1 nF, 2 kV, dielectric X7R, CMS) and Syfer 1812Y1K00473KXT (47 nF, 1 kV), respectively.

Power resistors 312 and 316 marketed by the company Bourns under the reference RWS10 1R J, for example each with a value of resistance of 1 Ω. A power resistor 322 marketed by the company Bourns under the reference PWR263S-20 may be used, for example with a value of resistance of 100 kΩ for an example of VHT of 800 V.

Advantageously, the control circuit 64 applies the gate voltage (for a controlled switch of type field-effect transistor) to an input of the acquisition device 5. The acquisition device 5 may thus perform a measurement over time of the gate voltage in order to guarantee the stability of the measurements.

In the examples detailed hereinabove, the voltage sources 311, 323 and 41 are DC voltage sources. It may also be envisioned for one or more of these voltage sources to be pulsed sources.

1. A system, comprising:
a power diode to be characterized having an anode and a cathode;
a characterization device for the power diode, including:
first and second power supply nodes, respectively connected to the anode and to the cathode of the power diode to be characterized;
a power supply comprising:
a first voltage source generating a first power supply potential and connected to the first power supply node;
a capacitor connected in parallel with said first voltage source;
a second voltage source generating a second power supply potential, the second potential being higher than the first potential;
a first resistor connected in series between the second voltage source and said second power supply node;
a controlled switch capable of selectively connecting the second power supply node to a potential lower than the first potential;
a voltage clipping circuit including:
a third voltage source;
a second resistor and a first diode connected in series between the third voltage source and said second power supply node, the first diode being connected in such a manner as to have a forward current flowing through it going from the third voltage source to said second power supply node;
a measurement terminal, connected to an intermediate node between the second resistor and the first diode.

2. The system as claimed in claim 1, wherein said voltage clipping circuit comprises:
a third resistor and a second diode connected in series between the third voltage source and said second power supply node;
an additional measurement terminal, connected to an intermediate node between the third resistor and the second diode.

3. The system as claimed in claim 1, wherein said voltage clipping circuit comprises third and fourth diodes, said third and fourth diodes and said second resistor being connected in parallel, the anode of the third diode being connected to the cathode of the fourth diode.

4. The system as claimed in claim 1, wherein said first diode has a forward-bias recovery time equal to 1 μs at the most and a breakdown voltage equal to at least 100 V.

5. The system as claimed in claim 1, further comprising a decoupling capacitor connected in parallel with said second voltage source.

6. The system as claimed in claim 1, wherein said controlled switch has a breakdown voltage equal to at least 100 V.

7. The system as claimed in claim 1, in which said controlled switch consists of a field-effect transistor.

8. The system as claimed in claim 1, wherein the first voltage source is configured for delivering a current equal to at least 1 A.

9. The system as claimed in claim 8, wherein the first voltage source is configured for generating a first power supply potential equal to 20 V at the most.

10. The system as claimed in claim 1, wherein the second voltage source is configured for generating a power supply potential equal to at least 100 V.

11. The system as claimed in claim 1, further comprising a third power supply node configured to be connected to a substrate of the power diode to be characterized, and in which the power supply circuit is configured for applying a potential to said third power supply node.

12. The system as claimed in claim 1, further comprising a control circuit configured for sequentially applying an opening signal and a closing signal to a control electrode of the controlled switch.

13. The system as claimed in claim 1, further comprising a measurement probe for the current between the first and second power supply nodes.

14. The system as claimed in claim 1, further comprising an acquisition device connected to said measurement terminal.

15. The system as claimed in claim 2, wherein said voltage clipping circuit comprises third and fourth diodes, said third and fourth diodes and said second resistor being connected in parallel, the anode of the third diode being connected to the cathode of the fourth diode.

16. The system as claimed in claim 15, wherein said first diode has a forward-bias recovery time equal to 1 μs at the most and a breakdown voltage equal to at least 100 V.

17. The system as claimed in claim 16, further comprising a decoupling capacitor connected in parallel with said second voltage source.

18. The system as claimed in claim 17, wherein said controlled switch has a breakdown voltage equal to at least 100 V.

19. The system as claimed in claim 18, in which said controlled switch consists of a field-effect transistor.

20. The system as claimed in claim 19, wherein the first voltage source is configured for delivering a current equal to at least 1 A.
